(19) United States
(12) Patent Application Publication
(10) Pub. No.: US 2016/0028412 A1
(43) Pub. Date: Jan. 28, 2016

(54) PIPELINED ANALOG-TO-DIGITAL CONVERTER

(71) Applicant: XINFENG QUANTEL TECHNOLOGIES (BEIJING)CO.,LTD, Beijing (CN)

(72) Inventors: Song LIU, Beijing (CN); Feiqin YANG, Beijing (CN); Ke WU, Beijing (CN)

(21) Appl. No.: 14/758,653

(22) PCT Filed: Dec. 31, 2012
(86) PCT No.: PCT/CN2012/088017

§ 371 Date: Oct. 16, 2015

(51) Int. Cl. H03M 1/00; H03M 1/74; H03M 1/08; H03M 1/12; H03M 1/16

(52) U.S. Cl. CPC H03M 1/002; H03M 1/1245; H03M 1/164; H03M 1/0836; H03M 1/74

(57) ABSTRACT

The invention provides a pipelined analog-digital converter (ADC) and pertains to the technical field of integrated circuit (IC) design. The pipelined ADC at least comprises: a sampling holder, n multiplier digital-analog converters that are connected stage by stage, a clock generator, a reference generator and a digital encoder, wherein at least the sampling holder and n multiplier digital-analog converters are substantially arranged in a loop so as to form an intermediate area in an encircling manner; the clock generator and the reference generator are disposed in the intermediate area so that the clock generator and the reference generator respectively provide corresponding signal inputs to the surrounding n multiplier digital-analog converters in a star connection. The pipelined ADC has an excellent performance and is in particular applicable to high speed/high accuracy application.

### CROSS REFERENCE TO RELATED APPLICATIONS

This is the U.S. national stage of application No. PCT/CN2012/088017, filed on Dec. 31, 2012, the disclosure of which is incorporated herein by reference.

### FIELD OF THE INVENTION

The invention pertains to the technical field of integrated circuit (IC) design, and relates to a pipelined analog-digital converter (ADC, or named as A/D converter) in which a main functional module thereof is arranged in a loop.

### BACKGROUND

An analog-digital converter (ADC) can convert a continuously varying analog signal into a digital signal to be output so as to provide a signal source for digital signal processing. Therefore, ADC is one of the indispensable components in a digital system, and is widely used in a digitalized and integrated electronic system.

One of the important parameters of ADC is the accuracy in conversion (also referred to as resolution), which is generally represented by the number of bits of the output digital signal; the more the number of bits of the digital signal that ADC can accurately output is, the greater the ADC's ability to recognize an input signal will be, the better the ADC's performance will be, and the more accurate the result of digital signal processing using digital signals will be. Another important parameter of ADC is the conversion speed, which is usually measured by the number of points sampled and converted for input analog signals per second. Other important parameters of ADC comprise chip area, power consumption, etc. Since ADC is substantially formed by being integrated into a chip, a layout is required to be made for it and the index of chip area is required to be measured; the smaller the area occupied by ADC is, the lower the power consumption will be, and the more popular it will become in the industry.

Currently, continuous efforts are being made in the industry to improve the performance of ADC in terms of aspects such as accuracy, speed, chip area and power consumption, etc.

Presently, pipelined ADC is a commonly used structure for ADC, which is mainly characterized by the followings: by converting signals in a stepwise manner, an increase of speed and accuracy as well as a reduction of chip area and power consumption; pipelined ADC plays a very important role in areas such as video processing, wireless communication, instruments and meters, etc.

However, in the application of more high speed/high accuracy ADC, since parasitic parameters (parasitic resistance/capacitance) of semiconductor devices and wirings are becoming more and more unnegligible, the layout of pipelined ADC is having a more and more important influence on the performance index thereof. Conventional layouts have shown their limitations nowadays when ADC speed and accuracy are increasing continuously, and have even to some extent become a bottleneck that restricts a further improvement of pipelined ADC performance.

In view of the above, the aim is to further improve pipelined ADC performance in terms of the layout of pipelined ADC.

### SUMMARY OF THE INVENTION

The object of the invention is to improve pipelined ADC performance.

In order to achieve the above or other objects, the invention provides a pipelined ADC which at least comprises:

n multiplier digital-analog converters (22-1, . . . , 22-n) that are connected stage by stage,

a clock generator (240),

a reference generator (250), and

a digital encoder (260);

wherein at least n multiplier digital-analog converters (22-1, . . . , 22-n) are substantially arranged in a loop so as to form an intermediate area (290) in an encircling manner; the clock generator (240) and the reference generator (250) are disposed in the intermediate area (290) so that the clock generator (240) and the reference generator (250) respectively provide corresponding signal inputs to the surrounding n multiplier digital-analog converters (22-1, . . . , 22-n) in a star connection;

wherein n is an integer larger than or equal to 2.

According to the pipelined ADC of an embodiment of the invention, the pipelined ADC further comprises a power bus (270) for supplying power, wherein the power bus (270) is arranged substantially in a loop so as to surround therein the sampling holder (210) and n multiplier digital-analog converters (22-1, . . . , 22-n) connected stage by stage. In this embodiment, the power bus also realizes supplying power to MDAC of each stage in an “outer loop” layout, which is advantageous for shortening the overall length of power supplying wirings and reducing parasitic resistance/capacitance. The lengths of power supplying wirings corresponding to MDAC of each stage are more uniform and consistent, thus facilitating improving pipelined ADC performance.

In the pipelined ADC according to any of the previous embodiments, the power bus (270) can be arranged in a square or rectangular loop.

According to the pipelined ADC of another embodiment of the invention, the pipelined ADC further comprises a sampling holder (210), wherein external analog signals are input from the sampling holder (210), which outputs signals to the multiplier digital-analog converter (22-1) of the first stage.

According to the pipelined ADC of further another embodiment of the invention, the pipelined ADC further comprises a flash ADC (230) for converting residual voltage signals output from the multiplier digital-analog converter (22-n) into the Least Significant Bit;

the flash ADC (230), the sampling holder (210) and the n multiplier digital-analog converters (22-1, . . . , 22-n) that are connected stage by stage are arranged substantially in a loop so as to form the intermediate area (290) in an encircling manner.

In the pipelined ADC according to any of the previous embodiments, the sampling holder (210), the n multiplier digital-analog converters (22-1, . . . , 22-n) and the flash ADC (230) are disposed in order and adjacent to each other in the direction of signal flow, and the sampling holder (210) and the flash ADC (230) are adjoined end-to-end to form the loop.

According to the pipelined ADC of still another embodiment of the invention, the sampling holder (210) and the n multiplier digital-analog converters (22-1, . . . , 22-n) are disposed in order and adjacent to each other according to the direction of signal flow, and the sampling holder (210) and the multiplier digital-analog converter (22-n) of the last stage are adjoined end-to-end to form the loop.

In the pipelined ADC according to any of the previous embodiments, the loop can be a rectangular loop or a square loop.

In the pipelined ADC according to any of the previous embodiments, the clock generator (240) and the reference generator (250) can be placed at a central area position of the intermediate area (290).

In the pipelined ADC according to any of the previous embodiments, the power bus (270) supplies power to the sampling holder (210), the n multiplier digital-analog converters (22-1, . . . , 22-n), the clock generator (240), the reference generator (250) and the digital encoder (260) via power supplying wirings.

In the pipelined ADC according to any of the previous embodiments, the digital encoder (260) is arranged outside the intermediate area (290).

The invention an bring about the following technical effects: by arranging the sampling holder and the n multiplier digital-analog converters or the like in a loop and placing the reference generator and the clock generator in the middle of the loop, a star connection among the reference generator or the clock generator, the sampling holder and the n multiplier digital-analog converters can be conveniently achieved. Such a loop layout and star connection facilitate a further reduction of the chip area of ADC; moreover, both the overall length of clock wirings and the overall length of reference voltage wirings can be reduced, thus reducing parasitic resistance/capacitance of wirings. In particular, the uniformity and consistency of the length among individual clock wirings can be improved, the uniformity and consistency of the length among reference voltage wirings can be also improved. The quality of clock signals, reference voltage signals or the like provided to individual modules can be improved, which has greatly increased the overall performance of pipelined ADC, making it highly applicable to high speed/high accuracy applications.

### BRIEF DESCRIPTION OF THE DRAWINGS

The above and other objects and advantages of the invention will become more fully apparent from the following detailed description made with reference to the accompanying drawings, in which identical or similar elements are denoted by identical reference signs.

FIG. 1 is a schematic view showing the structure of a conventional pipelined ADC; and

FIG. 2 is a schematic view showing the structure of a pipelined ADC according to an embodiment of the invention.

### DETAILED DESCRIPTION OF THE UTILITY MODEL

Some of many possible embodiments of the invention will be described below for the purpose of providing a basic understanding of the invention, rather than identifying key or crucial elements of the invention or defining the scope of protection. It will be appreciated that according to the technical solutions of the invention, those skilled in the art can propose other alternative implementations without departing from the spirit of the invention. Therefore, the following detailed embodiments and drawings serve to provide merely an exemplary description of the technical solutions of the invention, and should not be considered as the whole of the invention or as defining or limiting the technical solutions of the invention.

In the following description, for the sake of clearness and conciseness, not all the many components shown in the drawings are described with details. Many components shown in the drawings provide a disclosure of the invention that can be fully implemented for those skilled in the art. For those skilled in the art, the operations of many components are familiar and obvious.

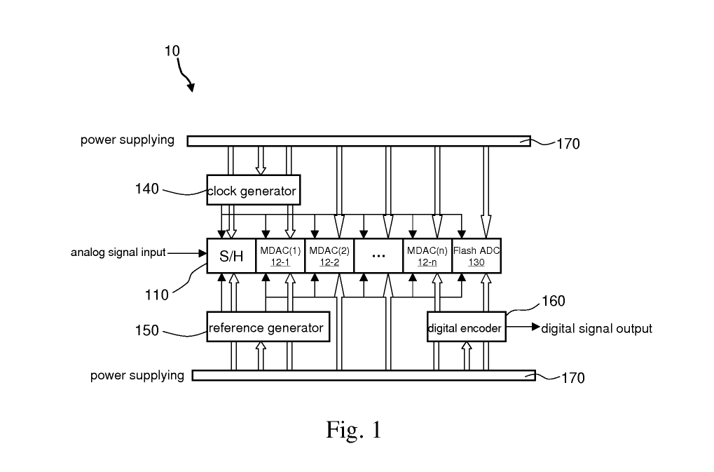

FIG. 1 is a schematic view showing the structure of a conventional pipelined ADC. In FIG. 1, the layout structure of various modules and the way of inputting signals are mainly shown. In this embodiment, the pipelined ADC 10 mainly comprises a sampling holder (S/H) 110, n multiplier digital-analog converters (12-1, . . . , 12-n) that are connected stage by stage, a flash ADC 130, a clock generator 140, a reference generator 150, a digital encoder 160 and power buses 170. In operation, an analog signal is input from the sampling holder 110, which samples the analog signal and then holds the voltage value thereof until next sampling point. By means of the sampling holder 110, a continuous analog signal can be converted into discrete sampling hold values so as to facilitate subsequent digital processing thereof; the discrete signals acquired after the processing of the sampling holder 110 are further output to a multiplier digital-analog converters(MDAC) 12-1 of the first stage, and are further quantized stage by stage in MDAC 12-1, . . . , 12-n respectively so as to generate a string of digital codes, which is deduced from a higher bit to a lower bit according to the flow direction of signals. For example, in the structure of pipelined ADC having 1.5 bit/stage, the MDAC of each stage contributes a bit of digital output; as the last stage, the flash ADC 130 can convert a residual voltage signal output by MDAC into a Least Significant Bit (LSB), thus giving the Least Significant Bit (least one or more bits) of the pipelined ADC 10; further, these digits are output to the digital encoder 160 having a delay calibrating function and a digit correcting function and are processed by the digital encoder 160. Then, a final output result of the entire pipelined ADC 10 is output, i.e., the digital signal output.

In the operation process schematically explained above, the pipelined ADC 10 shown in FIG. 1 must provides a clock signal to S/H 110, MDAC (12-1, . . . , 12-n) of each stage, the flash ADC 130 and the digital encoder 160 via the clock generator 140; meanwhile, the pipelined ADC 10 shown in FIG. 1 must for example provide a reference voltage signal to S/H 110, MDAC (12-1, . . . , 12-n) of each stage, the flash ADC 130 and the digital encoder 160 via the reference generator 150. Of course, the reference generator 150 has to simultaneously supply power to each operational module via the power buses 170.

In the layout of the pipelined ADC 10 shown in FIG. 1, the main functional modules thereof, such as S/H 110, n multiplier digital-analog converters (12-1, . . . , 12-n) that are connected stage by stage and the flash ADC 130, are arranged in order in a substantially “-” shape according to the flow direction of signals to be processed. The auxiliary functional modules therefore, such as the clock generator 140, the reference generator 150, the digital encoder 160 and the power buses 170 are disposed at two sides of the “-” shape so as to facilitate providing signal input to individual main functional modules. Specifically, as shown in FIG. 1, the clock output by the clock generator 140 is provided to each stage in sequence by way of buses. Generally, since S/H 110 has a high demand on clock jitter, the clock generator 140 is placed at an end closer to S/H 110. The higher the stage MDAC is, the further it is distant from the clock generator 140, and the flash ADC 130 is placed the farthest from the clock generator 140; meanwhile, the reference voltage generated by the reference generator 150 is also provided to each stage by way of buses. Generally, since MDAC of a previous stage has a higher importance, the reference generator 150 is generally placed beside MDAC of the previous stage, for example, closer to MDAC 12-1; the power buses 170 are also placed in a “-” shape substantially in parallel with each other, provide power voltage (VDD/VSS) to MDAC of each stage in sequence by way of buses, and meanwhile also provide power voltage to other modules (e.g., the clock generator 140, the reference generator 150 and the digital encoder 160).

When the layout of the pipelined ADC 10 according to the embodiment shown in FIG. 1 is designed in a way similar to FIG. 1, although some advantages are presented in terms of the reduction in chip area, the decrease of wiring length, etc., the following problems are becoming more and more prominent with the continuous improvement in speed/accuracy of ADC, etc.

Firstly, the wiring of clock drive is becoming longer with the increase of the number of stages of MDAC, the increase of load (caused by parasitic resistance/capacitance of wirings) leads to delay of clock, which is increased with the increase of the number of stages of MDAC; the difficulty in match/control of time sequence is increased, especially in case of high speed applications;

Secondly, the wiring of reference voltage is becoming longer with the increase of the number of stages of MDAC, the increase of load (caused by parasitic resistance/capacitance of wirings) leads to the increase of output impedance of driving source of reference voltage, thus increasing noise on the reference voltage (mainly caused by clock pulse). The wiring impedance is larger for the later stage. A direct consequence of this is that the reference voltages at individual stages are uneven, which will directly influence the accuracy of ADC.

Thirdly, the above problem also exists in the power supplying wirings from the power buses 170 to MDAC of each stage and the flash ADC 130, i.e., the lengths of power supplying wirings corresponding to MDAC of each stage and the flash ADC 130 are greatly inconsistent. The higher the stage is, the larger the parasitic resistance of power supplying wirings will be, thus leading to an increase of voltage drop and power supply noise (mainly caused by clock pulse).

The above problem directly restricts an improvement of the accuracy of pipelined ADC 10, and further restricts its application in high speed/high accuracy situations.

Chinese patent application No. CN201010018158.3, entitled “A layout structure of charge coupled pipelined ADC”, also discloses a layout structure similar to that in FIG. 1, and also has similar problems.

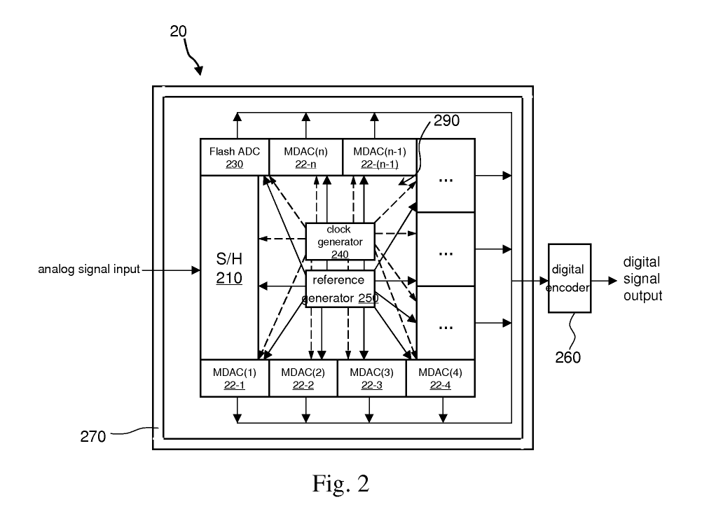

FIG. 2 is a schematic view showing the structure of a pipelined ADC according to an embodiment of the invention. In order to at least solve the problem with the pipelined ADC 10 according to the embodiment shown in FIG. 1, the layout of pipelined ADC is modified and improved. As shown in FIG. 2, the pipelined ADC 20 mainly comprises n multiplier digital-analog converters (22-1, . . . , 22-n) that are connected stage by stage, a clock generator 240, a reference generator 250, a digital encoder 260 and a power bus 270, wherein n is an integer larger than or equal to 2, e.g., n4. In this embodiment, the pipelined ADC 20 may further comprise a sampling holder (S/H) 210, a flash ADC 230; in operation, an analog signal is input from the sampling holder 210, which samples the analog signal and then holds the voltage value thereof until next sampling point. By means of the sampling holder 210, a continuous analog signal can be converted into discrete sampling hold values so as to facilitate subsequent digital processing thereof; as the last stage, the flash ADC 230 can convert a residual voltage signal output by MDAC into a Least Significant Bit (LSB), thus giving the least significant bit of the pipelined ADC 20. The MDACs are connected stage by stage according to the sequence of the signal flow, wherein the specific number is related to the number of stages of the pipelined ADC 20. Therefore, the number is not limiting, e.g., can be selected in a range of 4-12.

It is noted that in other embodiments, it is also possible that the flash ADC 230 is not used; instead, another MDAC (e.g., MDAC 22-(n+1)) is used to output the least significant bit. In further another embodiment, it is also possible not to use the sampling holder 210; instead, the external analog signal is input from MDAC 22-1 of the first stage, and MDAC 22-1 of the first stage accomplishes the sampling holding function.

With continued reference to FIG. 2, S/H 210, n multiplier digital-analog converters (22-1, . . . , 22-n) and the flash ADC 230, in layout design, can be arranged substantially in a loop. In this embodiment, in physical layout, S/H 210, n multiplier digital-analog converters (22-1, . . . , 22-n) and the flash ADC 230 are disposed in order and adjacent to each other in the direction of signal flow, and S/H 210 and the flash ADC 230 are adjoined end-to-end. Therefore, S/H 210, n multiplier digital-analog converters (22-1, . . . , 22-n) and the flash ADC 230 form a relatively closed intermediate area 290 in an encircling manner.

In other embodiments, when the pipelined ADC 20 is not provided with the flash ADC 230, S/H 210 can be adjoined to the MDAC 22-n arranged as the last stage end-to-end, thus forming a loop structure. In further another embodiment, when the pipelined ADC 20 is not provided with S/H 210, the MDAC 22-1 of the first stage can be adjoined to the MDAC 22-n arranged as the last stage end-to-end, thus forming a loop structure.

In this embodiment, the loop formed by S/H 210, n multiplier digital-analog converters (22-1, . . . , 22-n) and the flash ADC 230 adjoined in order end-to-end can be a rectangular loop or a square, circular or rhombus loop, and the specific shape is not limited to the embodiment shown in the drawings; specifically, a square or rectangular loop can be selectively provided. The specific shape of the intermediate area 290 is also not limited to the shape of the embodiment shown in the drawings.

Further, the intermediate area 290 is used to place the clock generator 240 and the reference generator 250. Therefore, the area of the intermediate area 290 can be set such that the intermediate area 290 can be at least used to place the clock generator 240 and the reference generator 250. The specific arrangement and layout of the clock generator 240 and the reference generator 250 in the intermediate area 290 is not limiting; in an embodiment, the clock generator 240 and the reference generator 250 can be prone to be placed at a central area position of the intermediate area 290 so that the lengths of the clock wirings (as shown by the dotted line arrow in FIG. 2) from the clock generator 240 to the S/H 210, n multiplier digital-analog converters (22-1, . . . , 22-n) and the flash ADC 230 has a better consistency and that the lengths of the reference voltage wirings (as shown by the solid line arrow in FIG. 2) from the reference generator 250 to the S/H 210, n multiplier digital-analog converters (22-1, . . . , 22-n) and the flash ADC 230 has a better consistency.

As shown in FIG. 2, when the clock generator 240 and the reference generator 250 are placed in the intermediate area 290, they can be connected to the surrounding main functional modules (S/H 210, n multiplier digital-analog converters (22-1, . . . , 22-n) and the flash ADC 230) that are arranged in a loop via diverging wirings in a star wirings manner. That is, the clock generator 240, as the center, forms clock wirings with the S/H 210, n multiplier digital-analog converters (22-1, . . . , 22-n) and the flash ADC 230 in a star connection manner (as shown by the dotted line arrow in FIG. 2) so as to provide clock signal input to each stage; the reference generator 250 forms reference voltage wirings with the S/H 210, n multiplier digital-analog converters (22-1, . . . , 22-n) and the flash ADC 230 in a star connection manner (as shown by the solid line arrow in FIG. 2) so as to provide reference voltage signal input to each stage.

Through the layout of S/H 210, n multiplier digital-analog converters (22-1, . . . , 22-n), the flash ADC 230, the clock generator 240 and the reference generator 250 in the above embodiment, the overall length of clock wirings is reduced, and the overall length of reference voltage wirings is reduced, thus reducing parasitic resistance/capacitance of wirings. Moreover, the lengths of clock wirings or reference voltage wirings connecting to individual main functional modules correspondingly in star distributions are uniform and consistent, and a phenomenon in which the length of clock wirings or reference voltage wirings become larger as the stage becomes higher is avoided. Therefore, the clock consistency of individual modules (S/H 210, n multiplier digital-analog converters (22-1, . . . , 22-n) and the flash ADC 230) and the consistency of reference voltage output impedance are improved, and the problems in the first aspect and the second aspect of the embodiment shown in FIG. 1 can be avoided, thus greatly improving the performance of pipelined ADC (e.g., the accuracy and speed are improved).

As further shown in FIG. 2, in this embodiment, the power bus 270 is disposed outside the S/H 210, n multiplier digital-analog converters (22-1, . . . , 22-n) and the flash ADC 230 in the loop, and is substantially arranged in a loop so as to encircle the S/H 210, n multiplier digital-analog converters (22-1, . . . , 22-n) and the flash ADC 230 therein. The loop structure of the power bus 270 can be a square shape loop, or a rectangular, circular or rhombus loop, etc., and the specific shape is not limited to the embodiment shown in the drawings. The power bus 270 in the loop can provide power supplying wirings (not shown in FIG. 2) to S/H 210, n multiplier digital-analog converters (22-1, . . . , 22-n), the flash ADC 230, the clock generator 240 and the reference generator 250 so as to supply power to them. In an embodiment, the loop structure of the power bus 270 can match the shape of the loop structure formed by S/H 210, n multiplier digital-analog converters (22-1, . . . , 22-n) and the flash ADC 230 so that the overall length of power supplying wirings of the power bus 270 is reduced.

The layout of the power bus 270 can also reduce the chip area and the overall length of power supplying wirings in pipelined ADC 20, and decrease the parasitic resistance/capacitance, which will directly improve the quality of power voltage acquired by each sub-module and reduce circuit noise and performance loss caused by parasitic parameters of wirings. Meanwhile, a phenomenon in which the length of power supplying wirings become larger as the stage becomes higher will not occur in the pipelined ADC 20 implemented in FIG. 2, thus improving consistency of the resistance of power supplying wirings of individual modules (S/H 210, n multiplier digital-analog converters (22-1, . . . , 22-n) and the flash ADC 230) and avoiding the problem in the third aspect of the embodiment shown in FIG. 1.

Further, optionally, as shown in FIG. 2, the digital encoder 260 is disposed outside the loop of the power bus 270. Therefore, the digital encoder 260 is at least arranged outside the intermediate area 290. The power bus 270 and the digital encoder 260 are connected via power supplying wirings so as to supply power to the digital encoder 260. The output signals of MDAC of each stage and the flash ADC 230 are input to the digital encoder 260 which has a delay calibrating function and a digit correcting function and finally outputs a relatively accurate digital signal.

It will be appreciated that in the above embodiment, the specific internal circuit structures of individual functional modules (such as S/H 210, n multiplier digital-analog converters (22-1, . . . , 22-n), the flash ADC 230, the clock generator 240, the reference generator 250 and the digital encoder 260) are not limiting.

The above examples mainly discuss the pipelined ADC of the invention. While only some of the embodiments of the invention are described, those skilled in the art will understand that the invention can be implemented in many other ways without departing the spirit and scope thereof. Therefore, the examples and embodiments should be considered as schematic instead of limiting. The invention can cover various variations and alternatives without departing from the spirit and scope of the invention defined by the appended claims.

1. A pipelined analog-digital converter (ADC), at least comprising:
n multiplier digital-analog converters that are connected stage by stage,
a clock generator,
a reference generator, and
a digital encoder;
characterized in that at least n multiplier digital-analog converters are substantially arranged in a loop so as to form an intermediate area in an encircling manner; the clock generator and the reference generator are disposed in the intermediate area so that the clock generator and the reference generator respectively provide corresponding signal inputs to the surrounding n multiplier digital-analog converters in a star connection;
wherein n is an integer larger than or equal to 2.

2. The pipelined ADC according to claim 1, characterized in that the pipelined ADC further comprises a power bus for supplying power, wherein the power bus is arranged substantially in a loop so as to surround therein the sampling holder and n multiplier digital-analog converters connected stage by stage.

3. The pipelined ADC according to claim 2, characterized in that the power bus is arranged in a square or rectangular loop.

4. The pipelined ADC according to claim 1, characterized in that the pipelined ADC further comprises a sampling holder, wherein external analog signals are input from the sampling holder, which outputs signals to the multiplier digital-analog converter of the first stage.

5. The pipelined ADC according to claim 4, characterized in that the pipelined ADC further comprises a flash ADC for converting residual voltage signals output from the multiplier digital-analog converter into the Least Significant Bit;
the flash ADC, the sampling holder and the n multiplier digital-analog converters that are connected stage by stage are arranged substantially in a loop so as to form the intermediate area in an encircling manner.

6. The pipelined ADC according to claim 5, characterized in that the sampling holder, the n multiplier digital-analog converters and the flash ADC are disposed in order and adjacent to each other according to the direction of signal flow, and the sampling holder and the flash ADC are adjoined end-to-end to form the loop.

7. The pipelined ADC according to claim 6, characterized in that the loop is a rectangular loop or a square loop.

8. The pipelined ADC according to claim 4, characterized in that the sampling holder and the n multiplier digital-analog converters are disposed in order and adjacent to each other according to the direction of signal flow, and the sampling holder and the multiplier digital-analog converter of the last stage are adjoined end-to-end to form the loop.

9. The pipelined ADC according to claim 1, characterized in that the clock generator and the reference generator are placed at a central area position of the intermediate area.

10. The pipelined ADC according to claim 4, characterized in that the power bus supplies power to the sampling holder, the n multiplier digital-analog converters, the clock generator, the reference generator and the digital encoder via power supplying wirings.

11. The pipelined ADC according to claim 1, characterized in that the digital encoder
is arranged outside the intermediate area.
